(19) United States
(12) Patent Application Publication
(10) Pub. No.: US 2023/0389322 A1
(43) Pub. Date: Nov. 30, 2023

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Dongjin LEE, Suwon-si (KR); Junhee LIM, Suwon-si (KR); Donghoon KWON, Suwon-si (KR); Hakseon KIM, Suwon-si (KR); Nakjin SON, Suwon-si (KR); Yanghee LEE, Suwon-si (KR); Juhyun LEE, Suwon-si (KR)

(73) Assignee: SAMSUNG ELECTRONICS CO., LTD., Suwon-si (KR)

(21) Appl. No.: 18/133,278

(22) Filed: Apr. 11, 2023

(30) Foreign Application Priority Data
May 30, 2022 (KR) 10-2022-0065842

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device includes a peripheral circuit region including a first substrate, circuit elements on the first substrate, a first interconnection structure electrically connected to the circuit elements, first to fourth peripheral region insulating layer; and a memory cell region including a second substrate on the peripheral circuit region and having a first region and a second region, gate electrodes stacked on the first region, a cell region insulating layer covering the gate electrodes, channel structures passing through the gate electrodes, and a second interconnection structure electrically connected to the gate electrodes and the channel structures. The peripheral circuit region further includes first to fourth lower protective layers, at least one of the first, second, third and fourth lower protective layers includes a hydrogen diffusion barrier layer configured to inhibit a hydrogen element included in the cell region insulating layer from diffusing to the circuit elements, and including aluminum oxide.

### CROSS-REFERENCE TO RELATED APPLICATION

This application claims priority to Korean Patent Application No. 10-2022-0065842 filed on May 30, 2022 in the Korean Intellectual Property Office, the disclosure of which is incorporated herein by reference in its entirety.

### BACKGROUND

The present disclosure relates to a semiconductor device and an electronic system including the same.

A semiconductor device capable of storing high-capacity data in an electronic system requiring data storage is in demand. Accordingly, a method for increasing a data storage capacity of a semiconductor device is being researched. For example, as a method for increasing the data storage capacity of a semiconductor device, a semiconductor device including three-dimensionally arranged memory cells instead of two-dimensionally has been proposed.

### SUMMARY

Example embodiments provide a semiconductor device having improved electrical characteristics and reliability.

Example embodiments provide an electronic system including a semiconductor device having improved electrical characteristics and reliability.

According to an aspect of an example embodiment, a semiconductor device includes: a peripheral circuit region including: a first substrate; circuit elements disposed on the first substrate; a first interconnection structure electrically connected to the circuit elements; a first peripheral region insulating layer covering the circuit elements; a second peripheral region insulating layer disposed on the first peripheral region insulating layer; a third peripheral region insulating layer disposed on the second peripheral region insulating layer; and a fourth peripheral region insulating layer disposed on the third peripheral region insulating layer; and a memory cell region including: a second substrate disposed on the peripheral circuit region and having a first region and a second region; gate electrodes stacked on the first region of the second substrate and spaced apart from each other in a first direction perpendicular to an upper surface of the second substrate, and extending in a stepped shape in a second direction perpendicular to the first direction, on the second region of the second substrate; interlayer insulating layers alternately stacked with the gate electrodes; a cell region insulating layer covering the gate electrodes; channel structures passing through the gate electrodes and vertically extending from the second substrate, each of the channel structures including a channel layer; and a second interconnection structure electrically connected to the gate electrodes and the channel structures, wherein the peripheral circuit region further includes: a first lower protective layer disposed below the first peripheral region insulating layer; a second lower protective layer disposed between the first peripheral region insulating layer and the second peripheral region insulating layer; a third lower protective layer disposed between the second peripheral region insulating layer and the third peripheral region insulating layer; and a fourth lower protective layer disposed between the third peripheral region insulating layer and the fourth peripheral region insulating layer, wherein at least one of the first lower protective layer, the second lower protective layer, the third lower protective layer, and the fourth lower protective layer includes a hydrogen diffusion barrier layer configured to inhibit a hydrogen element in the cell region insulating layer from diffusing to the circuit elements, and wherein the hydrogen diffusion barrier layer includes aluminum oxide.

According to an aspect of an example embodiment, a semiconductor device includes: a first substrate; circuit elements disposed on the first substrate; a first lower protective layer covering the circuit elements; a first peripheral region insulating layer disposed on the first lower protective layer; a first lower interconnection structure penetrating through the first peripheral region insulating layer, the first lower interconnection structure including a first lower contact plug and a first lower interconnection line; a second lower protective layer disposed on the first peripheral region insulating layer; a second peripheral region insulating layer disposed on the second lower protective layer; a second lower interconnection structure penetrating through the second peripheral region insulating layer, the second lower interconnection structure including a second lower contact plug and a second lower interconnection line; a third lower protective layer disposed on the second peripheral region insulating layer; a third peripheral region insulating layer disposed on the third lower protective layer; a third lower interconnection structure penetrating through the third peripheral region insulating layer, the third lower interconnection structure including a third lower contact plug and a third lower interconnection line; a fourth lower protective layer disposed on the third peripheral region insulating layer; a fourth peripheral region insulating layer disposed on the fourth lower protective layer; a memory structure disposed on the fourth peripheral region insulating layer, the memory structure including gate electrodes and channel structures passing through the gate electrodes; a first cell region insulating layer disposed on the fourth peripheral region insulating layer and covering the memory structure; and a first upper protective layer, a second cell region insulating layer, a second upper protective layer, and a third cell region insulating layer sequentially stacked on the first cell region insulating layer, wherein a thickness of the third lower interconnection line is greater than a thickness of each of the first lower interconnection line and the second lower interconnection line, wherein a thickness of each of the second lower protective layer and the third lower protective layer is less than a thickness of each of the first lower protective layer and the fourth lower protective layer and a thickness of each of the first upper protective layer and the second upper protective layer, wherein each of the second lower protective layer and the third lower protective layer includes a second material different from a first material of the first lower protective layer and the fourth lower protective layer, wherein each of the second lower protective layer and the third lower protective layer includes a hydrogen diffusion barrier layer configured to inhibit a hydrogen element each of in the first cell region insulating layer, the second cell region insulating layer, and the third cell region insulating layer from diffusing to the circuit elements, and the hydrogen diffusion barrier layer includes the second material, and wherein the second material is aluminum oxide.

According to an aspect of an example embodiment, an electronic system includes: a semiconductor device including: a first substrate; circuit elements on the first substrate; a first lower protective layer covering the circuit elements; a first peripheral region insulating layer disposed on the first lower protective layer; a first lower interconnection structure penetrating through the first peripheral region insulating layer, the first lower interconnection structure including a first lower contact plug and a first lower interconnection line; a second lower protective layer disposed on the first peripheral region insulating layer; a second peripheral region insulating layer disposed on the second lower protective layer; a second lower interconnection structure penetrating through the second peripheral region insulating layer, the second lower interconnection structure including a second lower contact plug and a second lower interconnection line; a third lower protective layer disposed on the second peripheral region insulating layer; a third peripheral region insulating layer disposed on the third lower protective layer; a third lower interconnection structure penetrating through the third peripheral region insulating layer and including a third lower contact plug and a third lower interconnection line; a fourth lower protective layer disposed on the third peripheral region insulating layer; a fourth peripheral region insulating layer disposed on the fourth lower protective layer; a memory structure disposed on the fourth peripheral region insulating layer, the memory structure including gate electrodes and channel structures passing through the gate electrodes; a first cell region insulating layer disposed on the fourth peripheral region insulating layer and covering the memory structure; and a first upper protective layer, a second cell region insulating layer, a second upper protective layer and a third cell region insulating layer sequentially stacked on the first cell region insulating layer, and input/output pads electrically connected to the circuit elements, wherein a thickness of the third lower interconnection line is greater than a thickness of each of the first lower interconnection line and the second lower interconnection line, wherein a thickness of each of the second lower protective layer and the third lower protective layer is less than a thickness of each of the first lower protective layer, the fourth lower protective layer, and a thickness of each of the first upper protective layer, the second upper protective layer, wherein each of the second lower protective layer and the third lower protective layer includes a second material different from a first material of the first upper protective layer and the fourth lower protective layer, wherein each of the second upper protective layer and the third lower protective layer includes a hydrogen diffusion barrier layer including the second material and configured to inhibit a hydrogen element in each of the first cell region insulating layer, the second cell region insulating layer, and the third cell region insulating layer from diffusing to the circuit elements; and a controller electrically connected to the semiconductor device through the input/output pads and configured to control the semiconductor device.

### BRIEF DESCRIPTION OF DRAWINGS

The above and other aspects, features, and advantages of the present disclosure concept will be more clearly understood from the following description of example embodiments, taken in conjunction with the accompanying drawings, in which:

FIG. 1A is a schematic cross-sectional view of a semiconductor device according to example embodiments;

FIG. 1B is a schematic cross-sectional view of a semiconductor device according to example embodiments;

FIG. 2 is a partially enlarged view of a semiconductor device according to example embodiments;

FIG. 3 is a partially enlarged view of a semiconductor device according to example embodiments;

FIG. 4 is a partially enlarged view of a semiconductor device according to example embodiments;

FIG. 5 is a partially enlarged view of a semiconductor device according to example embodiments;

FIG. 6 is a partially enlarged view of a semiconductor device according to example embodiments;

FIG. 7 is a partially enlarged view of a semiconductor device according to example embodiments;

FIG. 8 is a partially enlarged view of a semiconductor device according to example embodiments;

FIG. 9 is a partially enlarged view of a semiconductor device according to example embodiments;

FIGS. 10A, 10B, 10C, 10D, 10E, 10F, 10G, 10H, 10I, 10J, 10K and 10L are schematic cross-sectional views illustrating a method of manufacturing a semiconductor device according to example embodiments;

FIG. 11 is a diagram schematically illustrating an electronic system including a semiconductor device according to example embodiments;

FIG. 12 is a perspective view schematically illustrating an electronic system including a semiconductor device according to an example embodiment; and

FIG. 13 is a cross-sectional view schematically illustrating a semiconductor package according to an example embodiment.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

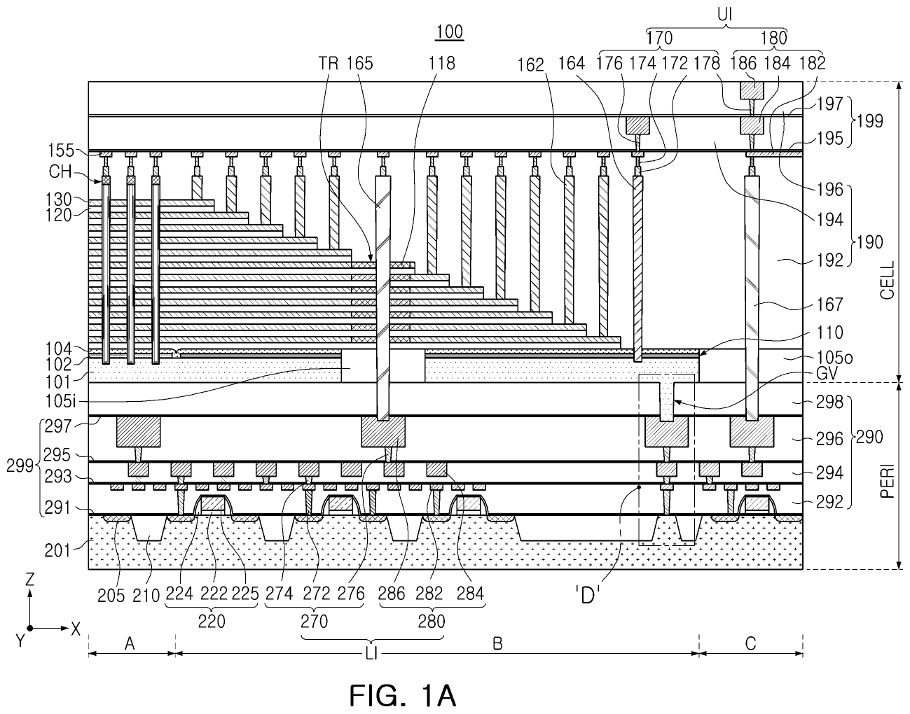

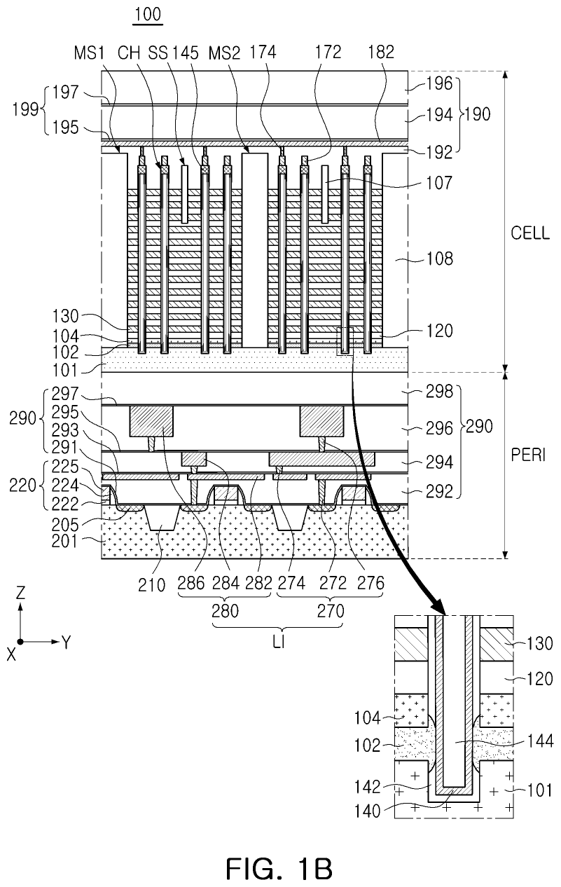

FIGS. 1A and 1B are schematic cross-sectional views of semiconductor devices according to example embodiments.

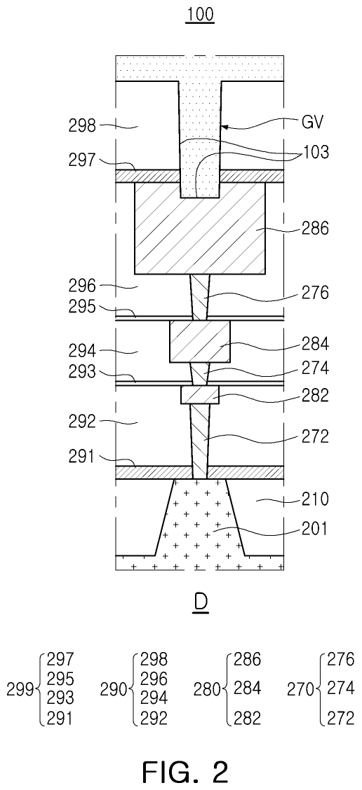

FIG. 2 is a partially enlarged view of a semiconductor device according to example embodiments. In FIG. 2, a region To′ of FIG. 1A is enlarged.

Referring to FIGS. 1A, 1B and 2, the semiconductor device 100 may include a peripheral circuit region PERI including a first substrate 201 and a memory cell region CELL including a second substrate 101. The memory cell region CELL may be disposed on top of the peripheral circuit region PERI. Conversely, in example embodiments, the cell region CELL may be disposed below the peripheral circuit region PERI.

The peripheral circuit region PERI may include a first substrate 201, source/drain regions 205 and device isolation layers 210 in the first substrate 201, circuit elements 220 disposed on the first substrate 201, a peripheral region insulating layer 290, a lower protective layer 299, and a first interconnection structure LI.

The first substrate 201 may have a top surface extending in the X-direction and the Y-direction. An active region may be defined in the first substrate 201 by the device isolation layers 210. Source/drain regions 205 including impurities may be disposed in a portion of the active region. The first substrate 201 may include a semiconductor material, for example, a group IV semiconductor, a group III-V compound semiconductor, or a group II-VI compound semiconductor. The first substrate 201 may be provided as a bulk wafer or as an epitaxial layer.

The circuit elements 220 may include transistors. Each of the circuit elements 220 may include a circuit gate dielectric layer 222, a spacer layer 224, and a circuit gate electrode 225. Source/drain regions 205 may be disposed in the first substrate 201 on both sides of the circuit gate electrode 225.

The peripheral region insulating layer 290 may be disposed on the circuit element 220 on the first substrate 201. The peripheral region insulating layer 290 may include first, second, third and fourth peripheral region insulating layers 292, 294, 296, and 298. First, second, third and fourth lower protective layers 291, 293, 295, and 297 may be disposed below the first, second, third and fourth peripheral region insulating layers 292, 294, 296, and 298, respectively. The peripheral region insulating layer 290 may be formed of an insulating material.

The lower protective layers 299 may include first, second, third and fourth lower protective layers 291, 293, 295, and 297. The first, second, third and fourth lower protective layers 291, 293, 295, and 297 may be disposed below the first, second, third and fourth peripheral region insulating layers 292, 294, 296 and 298, respectively. The second, third and fourth lower protective layers 293, 295, and 297 may be disposed between the first, second, third and fourth peripheral region insulating layers 292, 294, 296, and 298, respectively, and may be disposed on the first, second and third lower interconnection lines 282, 284, and 286. The second, third and fourth lower protective layers 293, 295, and 297 may be layers for preventing contamination of the lower interconnection lines 280 from the metal material. The lower protective layers 299 may be formed of an insulating material different from that of the peripheral region insulating layer 290, and for example, may include silicon nitride, aluminum oxide, or a combination thereof. However, example embodiments are not limited to this configuration.

The lower protective layers 299 may block diffusion of hydrogen. At least one of the lower protective layers 299 may include a hydrogen diffusion barrier layer that prevents a hydrogen element included in the cell region insulating layer 190 from diffusing into the circuit elements 220. The hydrogen diffusion barrier layer may include, for example, aluminum oxide. The first, second and third lower protective layers 291, 293 and 295 may block diffusion of the hydrogen element included in the first, second and third peripheral region insulating layers 292, 294 and 296 to the circuit elements 220, respectively. The fourth lower protective layer 297 may block diffusion of the hydrogen element included in the fourth peripheral region insulating layer 298 and the cell region insulating layer 190 to the circuit elements 220. Accordingly, because a defect in which the performance of the circuit elements 220 is deteriorated due to hydrogen may be prevented, a semiconductor device having improved productivity may be provided.

When, according to an example embodiment, the lower protective layers 299 include aluminum oxide, as the hydrogen diffusion length (H-Diffusion Length) is shorter than when the lower protective layers 299 include silicon nitride, the ability to block elemental hydrogen from diffusing may be relatively good. For example, as the hydrogen diffusion distance of aluminum oxide is about 3.5 nm, compared with silicon nitride, which has a hydrogen diffusion distance of about 200 nm, the hydrogen diffusion distance may be shortened by about 57 times, and compared with silicon oxide, which has a hydrogen diffusion distance of about 66 mm, the hydrogen diffusion distance may be shortened by about 18 million times.

Referring to FIG. 2, according to an example embodiment, the first and fourth lower protective layers 291 and 297 may include silicon nitride, and the second and third lower protective layers 293 and 295 may include aluminum oxide. The lower end of the first lower protective layer 291 is located at substantially the same level as the upper end of the first substrate 201, and lower ends of the second, third and fourth lower protective layers 293, 295, and 297 may be positioned at substantially the same level as upper ends of the first, second and third lower interconnection lines 282, 284, and 286. The first, second and third lower protective layers 291, 293, and 295 may be penetrated by the first, second and third lower contact plugs 272, 274 and 276, and the fourth lower interconnection line 297 may be formed through an upper via GV and through vias 165. The first lower protective layer and the fourth lower protective layers 291 and 297 and the second lower protective layer and the third lower protective layers 293 and 295 may include different materials, and for example, the first lower protective layer and the fourth lower protective layers 291 and 297 may include silicon nitride, and the second lower protective layer and the third lower protective layers 293 and 295 may include aluminum oxide.

The first lower protective layer and the fourth lower protective layers 291 and 297 and the second lower protective layer and the third lower protective layers 293 and 295 may have different thickness ranges. In an example embodiment, in order to prevent degradation of the performance of the semiconductor device 100 due to hydrogen diffusion, the first lower protective layer and the fourth lower protective layer 291 and 297 have a thickness in the range of about 300 Å to about 2000 Å, and the second lower protective layer and the third lower protective layers 293 and 295 may have a thickness in a range of about 50 Å to about 100 Å.

The first interconnection structure LI may be an interconnection structure electrically connected to the circuit elements 220 and the source/drain regions 205. The first interconnection structure LI may include column-shaped lower contact plugs 270 and line-shaped lower interconnection lines 280. The lower contact plugs 270 may include first, second and third lower contact plugs 272, 274, and 276. The first lower contact plugs 272 may be disposed on the circuit elements 220 and the source/drain regions 205, the second lower contact plugs 274 may be disposed on the first lower interconnection lines 282, and the third lower contact plugs 276 may be disposed on the second lower interconnection lines 284. The lower interconnection lines 280 may include first, second and third lower interconnection lines 282, 284, and 286. The first lower interconnection lines 282 may be disposed on the first lower contact plugs 272, the second lower interconnection lines 284 may be disposed on the second lower contact plugs 274, and the third lower interconnection lines 286 may be disposed on the third lower contact plugs 276. The first interconnection structure LI may include a conductive material, for example, tungsten (W), copper (Cu), aluminum (Al), or the like. Each of the components may further include a diffusion barrier. However, in example embodiments, the number of layers and the arrangement of the lower contact plugs 270 and the lower interconnection lines 280 constituting the first interconnection structure LI may be variously changed.

The memory cell region CELL may include a second substrate 101 having a first region A and a second region B, first and second horizontal conductive layers 102, 104 on the second substrate 101, a horizontal insulating layer 110 disposed in parallel with the first horizontal conductive layer 102 on the second region B of the second substrate 101, gate electrodes 130 stacked on the second substrate 101, first and second isolation regions MS1 and MS2 extending through the stacked structure of the gate electrodes 130, upper separation regions SS penetrating a portion of the stacked structure, channel structures CH disposed to penetrate the stacked structure, and a second interconnection structure UI electrically connected to the gate electrodes 130 and the channel structures CH. The memory cell region CELL may further include substrate insulating layers 105i, 105o, interlayer insulating layers 120 alternately stacked with the gate electrodes 130 on the second substrate 101, gate contacts 162 connected to the gate electrodes 130, a substrate contact 164 connected to the second substrate 101, a cell region insulating layer 190 covering the gate electrodes 130, and upper protective layer 199. The memory cell region CELL may further have a third region C outside the second substrate 101, and a through interconnection structure such as a second through via 167 connecting the memory cell region CELL and the peripheral circuit region PERI may be disposed in the third region C.

The first region A of the second substrate 101 may be a region in which the gate electrodes 130 may be vertically stacked and the channel structures CH may be disposed, and may be a region in which memory cells are disposed, and the second region B may be a region in which the gate electrodes 130 extend to have different lengths, and may correspond to a region for electrically connecting the memory cells to the peripheral circuit region PERI. The second region B may be disposed at at least one end of the first region Ain at least one direction, for example, the X-direction.

The second substrate 101 may have an upper surface extending in the X-direction and the Y-direction. The second substrate 101 may include a semiconductor material, for example, a group IV semiconductor, a group III-V compound semiconductor, or a group II-VI compound semiconductor. For example, the group IV semiconductor may include silicon, germanium, or silicon-germanium. The second substrate 101 may further include impurities. The second substrate 101 may be provided as a polycrystalline semiconductor layer such as a polycrystalline silicon layer or an epitaxial layer. The second substrate 101 may have a substantially flat upper surface and a non-planar lower surface protruded by the upper via GV.

The first and second horizontal conductive layers 102 and 104 may be stacked on an upper surface of the second substrate 101. At least a portion of the first and second horizontal conductive layers 102, 104 may function as part of a common source line of the semiconductor device 100, and for example, may function as a common source line together with the second substrate 101. As illustrated in the enlarged view of FIG. 1B, the first horizontal conductive layer 102 may be directly connected to the channel layer 140 around the channel layer 140. The first and second horizontal conductive layers 102 and 104 may include a semiconductor material, such as polycrystalline silicon. In this case, at least the first horizontal conductive layer 102 may be a doped layer, and the second horizontal conductive layer 104 may be a doped layer or a layer containing impurities diffused from the first horizontal conductive layer 102.

The horizontal insulating layer 110 may be disposed on the second substrate 101 in parallel to the first horizontal conductive layer 102 in at least a portion of the second region B. The horizontal insulating layer 110 may be layers remaining after a portion of the horizontal insulating layer 110 is replaced with the second horizontal conductive layer 104 in the manufacturing process of the semiconductor device 100.

The horizontal insulating layer 110 may include, for example, silicon oxide, silicon nitride, silicon carbide, or silicon oxynitride. In an example embodiment, the horizontal insulating layer 110 may include first, second and third horizontal insulating layers sequentially stacked, the first and third horizontal insulating layers may be silicon oxide layers and the second horizontal insulating layer may be a silicon nitride layer.

The substrate insulating layers 105i and 105o may be disposed in a region from which a portion of the second substrate 101 and the first and second horizontal conductive layers 102 and 104 and the horizontal insulating layer 110 are removed, and may be disposed to contact side surfaces of the second substrate 101, the first and second horizontal conductive layers 102 and 104, and the horizontal insulating layer 110. According to an example embodiment, the lower surfaces of the substrate insulating layers 105i and 105o may be coplanar with the lower surface of the second substrate 101 or, according to an example embodiment, may be located at a level lower than the lower surface of the second substrate 101. In some example embodiments, the substrate insulating layers 105i and 105o may be disposed in a region where only the second substrate 101 is removed. In this case, the substrate insulating layers 105i and 105o may have an upper surface substantially coplanar with the upper surface of the second substrate 101, and a separate insulating layer disposed to be surrounded by the first and second horizontal conductive layers 102 and 104 may be further disposed on the upper portion. The substrate insulating layers 105i and 105o may be formed of an insulating material, and may include, for example, silicon oxide, silicon oxynitride, or silicon nitride.

The gate electrodes 130 may be vertically spaced apart and stacked on the second substrate 101 to form a stacked structure. The gate electrodes 130 may include electrodes forming a ground selection transistor, memory cells, and a string selection transistor sequentially from the second substrate 101. The number of gate electrodes 130 constituting the memory cells may be determined according to the capacity of the semiconductor device 100. According to an example embodiment, each of the gate electrodes 130 constituting the string selection transistor and the ground selection transistor may be one or two or more, and the structure may be the same as or different from that of the gate electrodes 130 of the memory cells. In addition, the gate electrodes 130 may be disposed on the gate electrode 130 constituting the string selection transistor, and the gate electrode 130 may further include an erase transistor used for an erase operation using a gate induced drain leakage (GIDL) phenomenon. Some of the gate electrodes 130, for example, the gate electrodes 130 adjacent to the gate electrode 130 constituting the string select transistor and the ground select transistor may be dummy gate electrodes.

The gate electrodes 130 may be vertically spaced apart from each other and stacked on the first region A, and may extend from the first region A to the second region B at different lengths to form a stepped structure. As illustrated in FIG. 1A, the gate electrodes 130 may form a stepped structure between the gate electrodes 130 in the X-direction. In some example embodiments, in at least some of the gate electrodes 130, a certain number, for example, two to six gate electrodes 130, form one gate group, a stepped structure may be formed between the gate groups in the X-direction. In this case, the gate electrodes 130 constituting the one gate group may be disposed to have a stepped structure in the Y-direction as well. Due to the step structure, the gate electrodes 130 may form a stepped shape in which the lower gate electrode 130 extends longer than the upper gate electrode 130. End portions exposed upward from the interlayer insulating layers 120 may be provided. In some example embodiments, at the ends, the gate electrodes 130 may have an upward thickness.

The gate electrodes 130 may include a metal material, for example, tungsten (W). In some example embodiments, the gate electrodes 130 may include polycrystalline silicon or a metal silicide material. In example embodiments, the gate electrodes 130 may further include a diffusion barrier layer, and for example, the diffusion barrier layer may include tungsten nitride (WN), tantalum nitride (TaN), titanium nitride (TiN), or a combination thereof.

The interlayer insulating layers 120 may be disposed between the gate electrodes 130. The interlayer insulating layers 120 may also be spaced apart from each other in a direction perpendicular to the top surface of the second substrate 101, like the gate electrodes 130, and may be arranged to extend in the X-direction. The interlayer insulating layers 120 may include an insulating material such as silicon oxide or silicon nitride.

The first and second separation regions MS1 and MS2 may pass through the gate electrodes 130 in the first region A and the second region B, and may be arranged to extend along the X-direction. The first and second separation regions MS1 and MS2 may extend parallel to each other. As illustrated in FIG. 1B, the first and second separation regions MS1 and MS2 may penetrate the entire gate electrodes 130 stacked on the second substrate 101 to be connected to the second substrate 101. The first separation region MS1 may extend as one along the first region A and the second region B, and the second separation region MS2 may extend only to a portion of the second region B, or may be intermittently disposed in the first region A and the second region B. However, in example embodiments, the arrangement order and arrangement interval of the first and second separation regions MS1 and MS2 may be variously changed.

An isolation insulating layer 108 may be disposed in the first and second isolation regions MS1 and MS2. In some example embodiments, the isolation insulating layer 108 may have a shape in which the width decreases toward the second substrate 101 due to a high aspect ratio. However, in example embodiments, a conductive layer may be further disposed between the isolation insulating layer 108 in the first and second isolation regions MS1 and MS2. In this case, the conductive layer may function as a common source line or a contact plug connected to the common source line of the semiconductor device 100.

The upper separation regions SS may extend in the X-direction between the first separation region MS1 and the second separation region MS2. The upper isolation regions SS may pass through some of the gate electrodes 130 including the uppermost gate electrode 130 among the gate electrodes 130, and may be disposed in a portion of the second region B and a portion of the first region A. As illustrated in FIG. 1B, the upper isolation regions SS may separate, for example, a total of three gate electrodes 130 from each other in the Y-direction. However, the number of gate electrodes 130 separated by the upper isolation regions SS may be variously changed in some example embodiments. The upper isolation regions SS may include an upper isolation insulating layer 107.

Each of the channel structures CH may constitute one memory cell string, and the rows and columns may be formed on the first region A and may be spaced apart from each other. The channel structures CH may be disposed to form a grid pattern in the X-Y plane or may be disposed in a zigzag shape in one direction. The channel structures CH may have a columnar shape, and may have inclined sides that become narrower as they get closer to the second substrate 101 according to an aspect ratio. In example embodiments, dummy channels that do not substantially form a memory cell string may be further disposed at the end of the first region A and the second region B adjacent to the second region B.

As illustrated in the enlarged view of FIG. 1B, the channel layer 140 may be disposed in the channel structures CH. In the channel structures CH, the channel layer 140 may be formed in an annular shape surrounding the channel insulating layer 144 therein. In some example embodiments, the channel insulating layer 144 may have a columnar shape such as a column or a prism even without the channel insulating layer 144. The channel layer 140 may be connected to the first horizontal conductive layer 102 at a lower portion of the first horizontal conductive layer 102. The channel layer 140 may include a semiconductor material such as polycrystalline silicon or single crystal silicon. The channel structures CH may be disposed on a straight line in the Y-direction between the first or second isolation regions MS1 and MS2 and the upper isolation region SS. The channel structures CH may be electrically separated from each other by a second interconnection structure UI connected to the channel pads 155.

In the channel structures CH, channel pads 155 may be disposed on the channel layer 140. The channel pads 155 may be disposed to cover the upper surface of the channel insulating layer 144 and be electrically connected to the channel layer 140. The channel pads 155 may include, for example, doped polycrystalline silicon.

The gate dielectric layer 145 may be disposed between the gate electrodes 130 and the channel layer 140. Although not specifically illustrated, the gate dielectric layer 145 may include a tunneling layer, a charge storage layer, and a blocking layer sequentially stacked from the channel layer 140. The tunneling layer may tunnel charge into the charge storage layer, and for example, may include silicon oxide (SiO2), silicon nitride (Si3N4), silicon oxynitride (SiON), or a combination thereof. The charge storage layer may be a charge trap layer or a floating gate conductive layer. The blocking layer may include silicon oxide (SiO2), silicon nitride (Si3N4), silicon oxynitride (SiON), a high-k dielectric material, or a combination thereof. In example embodiments, at least a portion of the gate dielectric layer 145 may extend in a horizontal direction along the gate electrodes 130.

The cell region insulating layer 190 may be disposed to cover the second substrate 101, the gate electrodes 130 on the second substrate 101, and the peripheral region insulating layer 290. The cell region insulating layers 190 may include first, second and third cell region insulating layers 192, 194, and 196, and the first, second and third cell region insulating layers 192, 194, and 196 each may include a plurality of insulating layers. The cell region insulating layers 190 may be formed of an insulating material.

The upper protective layer 199 may include first and second upper protective layers 195 and 197. Between the first and second cell region insulating layers 192 and 194, a first upper protective layer 195 may be disposed on top surfaces of the first upper interconnection lines 182. The second upper protective layer 197 may be disposed on the upper surfaces of the second upper interconnection lines 184 between the second and third cell region insulating layers 194 and 196. In example embodiments, the upper protective layer 199 may be further disposed on the upper surfaces of the third upper interconnection lines 186. The upper protective layer 199 may be a layer for preventing contamination of the upper interconnection lines 180 disposed thereunder due to a metal material. The upper protective layer 199 may be formed of an insulating material different from that of the cell region insulating layer 190, and may include, for example, silicon nitride.

The gate contacts 162 may be connected to the gate electrodes 130 in the second region B. The gate contacts 162 may pass through at least a portion of the first cell region insulating layer 192 and may be disposed to be connected to each of the gate electrodes 130 exposed upwards. The substrate contact 164 may be connected to the second substrate 101 at an end of the second region B. The substrate contact 164 may penetrate through at least a portion of the first cell region insulating layer 192 and through the first and second horizontal conductive layers 102 and 104 exposed upwards, and may be connected to the second substrate 101. The substrate contact 164 may apply an electrical signal to, for example, a common source line including the second substrate 101.

The second interconnection structure UI may be an interconnection structure electrically connected to the gate electrodes 130 and the channel structures CH. The second interconnection structure UI may include column-shaped upper contact plugs 170 and line-shaped upper interconnection lines 180. The upper contact plugs 170 may include first, second, third and fourth upper contact plugs 172, 174, 176, and 178. The first upper contact plugs 172 are disposed on the channel pads 155 and the gate contacts 162, the second upper contact plugs 174 are disposed on the first upper contact plugs 172, the third upper contact plugs 176 may be disposed on the first upper interconnection lines 182, and the fourth upper contact plugs 178 may be disposed on the second upper interconnection lines 184. The upper interconnection lines 180 may include first, second and third upper interconnection lines 182, 184, and 186. The first upper interconnection lines 182 may be disposed on the second upper contact plugs 174, the second upper interconnection lines 184 may be disposed on the third upper contact plugs 176, and the third The upper interconnection lines 186 may be disposed on the fourth upper contact plugs 178. The second interconnection structure UI may include a conductive material, and for example, may include tungsten (W), copper (Cu), aluminum (Al), or the like, and each may further include a diffusion barrier layer. However, in example embodiments, the number of layers and the arrangement of the upper contact plugs 170 and the upper interconnection lines 180 constituting the second interconnection structure UI may be variously changed.

The through-interconnection region TR may be a region including a through interconnection structure for electrically connecting the memory cell region CELL and the peripheral circuit region PERI to each other. The through-interconnection region TR may include a first through-via 165 extending in the Z-direction through the second substrate 101 from an upper portion of the memory cell region CELL, and an insulation region surrounding the first through via 165. The insulating region may include sacrificial insulating layers 118, interlayer insulating layers 120 disposed perpendicular to the sacrificial insulating layers 118, and an inner substrate insulating layer 105i. In example embodiments, the size, arrangement, and shape of the through interconnection region TR may be variously changed. In FIG. 1A, the through-interconnection region TR is illustrated as being disposed in the second region B, but is not limited thereto, and may also be arranged at predetermined intervals in the first region A. The through-interconnection region TR may be spaced apart from the first and second separation regions MS1 and MS2. For example, the through-interconnection region TR may be disposed at a center of a pair of adjacent first separation regions MS1 in the Y-direction. With this arrangement, the sacrificial insulating layers 118 may remain in the through-interconnection region TR.

The first through via 165 passes through a portion of the first cell region insulating layer 192, the insulating region, the lower protective layer 295, and the second peripheral region insulating layer 294 from the top, and may extend perpendicularly to the upper surface of the second substrate 101. An upper end of the first through-via 165 may be connected to the second interconnection structure UI, and a lower end of the first through-via 165 may be connected to the first interconnection structure LI. In example embodiments, the number, arrangement, and shape of the first through vial 65 in one through interconnection region TR may be variously changed. The first through via 165 may include a conductive material, for example, a metal material such as tungsten (W), copper (Cu), or aluminum (Al).

The sacrificial insulating layers 118 may be positioned at the same height level as the gate electrodes 130 and may have the same thickness, and the gate electrodes 130 and side surfaces may be in contact with each other at the boundary of the through-interconnection region TR. The sacrificial insulating layers 118 may be alternately stacked with the interlayer insulating layers 120 to form the insulating region. The sacrificial insulating layers 118 may be disposed to have the same or different width as the lower inner substrate insulating layer 105i. The sacrificial insulating layers 118 may be formed of an insulating material different from that of the interlayer insulating layers 120 and may include, for example, silicon oxide, silicon nitride, or silicon oxynitride.

The second through via 167 may be disposed in the third region C of the memory cell region CELL, which is an external region of the second substrate 101, and may extend to the peripheral circuit region PERI. The second through via 167 may be disposed to connect the second interconnection structure UI and the first interconnection structure LI similarly to the first through via 165 of the through-interconnection region TR. However, the second through via 167 may extend from an upper portion through only a portion of the first cell region insulating layer 192 and the second peripheral region insulating layer 294. The second through via 167 may include a conductive material, for example, a metal material such as tungsten (W), copper (Cu), or aluminum (Al).

The upper via GV may be directly connected to the third lower interconnection line 286 through the second peripheral region insulating layer 294 and the lower protective layer 295. The upper via GV may be integrated with the second substrate 101 of the memory cell region CELL. As illustrated in FIG. 1A, the upper via GV may have a shape in which the second substrate 101 extends into the via hole toward the first substrate 201. The upper via GV may be formed together with the second substrate 101 to include the same material as the second substrate 101, and a boundary from the second substrate 101 may not exist.

The upper via GV may further include a barrier layer 103 extending from a lower surface of the second substrate 101 in addition to the second substrate 101. The barrier layer 103 may extend from the lower surface of the second substrate 101 along the inner wall of the via hole to cover the bottom surface of the via hole. The barrier layer 103 may include a metal nitride, for example, titanium nitride (TiN), titanium silicon nitride (TiSiN), tungsten nitride (WN), tantalum nitride (TaN), or a combination thereof. In the upper via GV, when, according to an example embodiment, a region extending from the second substrate 101 includes a semiconductor material and the third lower interconnection line 286 includes a metal material, defects may occur at the semiconductor-metal interface. However, even in this example embodiment, the barrier layer 103 is disposed between the semiconductor layer of the upper via GV integrated with the second substrate 101 and the lower interconnection lines 280, so that the upper via GV is formed. According to this example embodiment, the occurrence of the above defects may be suppressed.

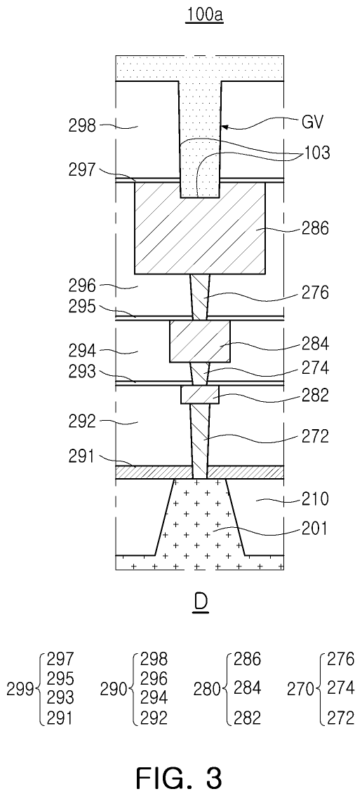

FIG. 3 is a partially enlarged view of a semiconductor device according to example embodiments. FIG. 3 is an enlarged view of an region corresponding to region ‘D’ of FIG. 1, according to an example embodiment.

Referring to FIG. 3, in the semiconductor device 100a, unlike the example embodiment of FIG. 2, the fourth lower protective layer 297 includes the same material as the second and third lower protective layers 293 and 295, and for example, may include silicon nitride. The fourth lower protective layer 297 may have a thickness in the same range as that of the second and third lower protective layers 293 and 295. For example, the fourth lower protective layer 297 may have a thickness in a range of about 50 Å to about 100 Å.

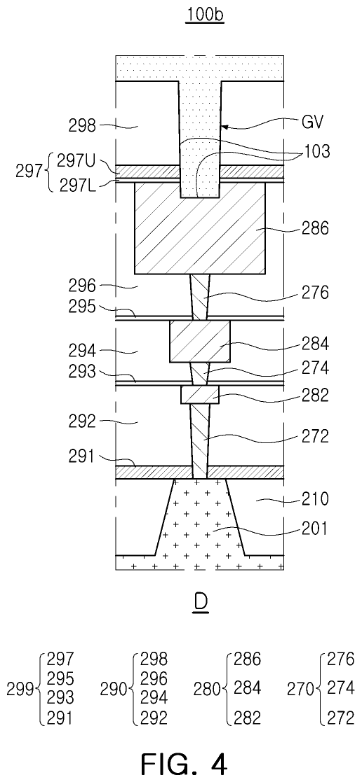

FIG. 4 is a partially enlarged view of a semiconductor device according to example embodiments. FIG. 4 illustrates an enlarged region corresponding to region ‘D’ in FIG. 1, according to an example embodiment.

Referring to FIG. 4, in the semiconductor device 100b, unlike the example embodiment of FIG. 2, a fourth lower protective layer 297 may have a double layer structure in which a second sub passivation layer 297U comprising silicon nitride is stacked on a first sub passivation layer 297L comprising aluminum oxide (297U, ‘297U’ are not shown in FIGs). The fourth lower protective layer 297 may have a thickness in a range of about 350 Å to about 2100 Å.

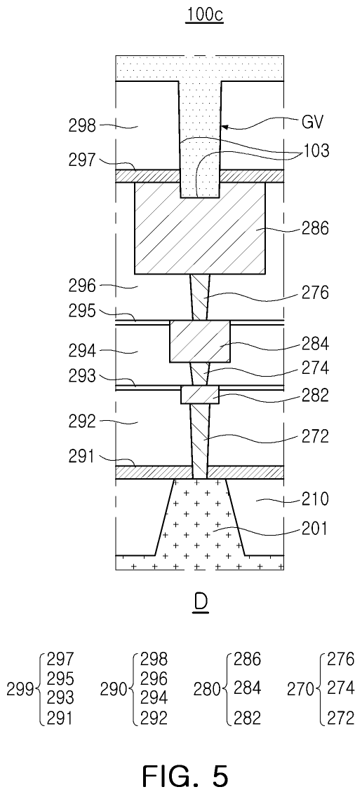

FIG. 5 is a partially enlarged view of a semiconductor device according to example embodiments. FIG. 5 illustrates an enlarged region corresponding to region ‘D’ in FIG. 1, according to an example embodiment.

Referring to FIG. 5, in the semiconductor device 100c, unlike the example embodiment of FIG. 2, top surfaces of the second and third lower protective layers 293 and 295 may be respectively located at substantially the same level as the upper surfaces of the first and second lower interconnection lines 282 and 284. The second and third lower protective layers 293 and 295 may have a structure in which they are cut off by the first and second lower interconnection lines 282 and 284.

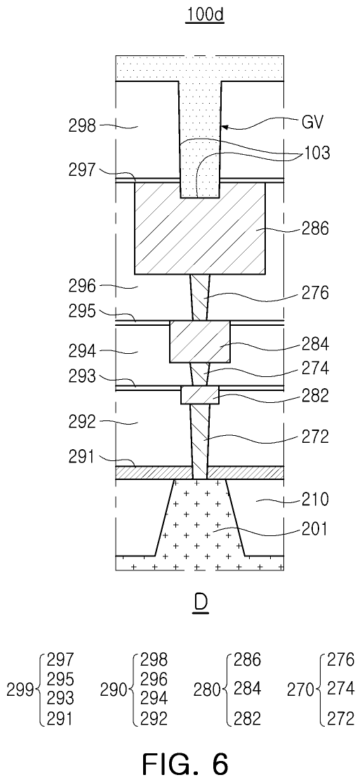

FIG. 6 is a partially enlarged view of a semiconductor device according to example embodiments. FIG. 6 illustrates an enlarged region corresponding to region ‘D’ in FIG. 1, according to an example embodiment.

Referring to FIG. 6, in the semiconductor device 100d, unlike in the example embodiment of FIG. 2, top surfaces of the second and third lower protective layers 293 and 295 are first and second lower interconnection lines, respectively. It may be located at substantially the same level as the upper surfaces of the first and second lower interconnection lines 282 and 284. Top surfaces of the second and third lower protective layers 293 and 295 may be coplanar with top surfaces of the first and second lower interconnection lines 282 and 284, respectively. The second and third lower protective layers 293 and 295 may have a structure in which they are cut off by the first and second lower interconnection lines 282 and 284.

The fourth lower protective layer 297 may include the same material as the second and third lower protective layers 293 and 295, for example, silicon nitride. The fourth lower protective layer 297 may have a thickness in the same range as that of the second and third lower protective layers 293 and 295. For example, the fourth lower protective layer 297 may have a thickness in a range of about 50 Å to about 100 Å.

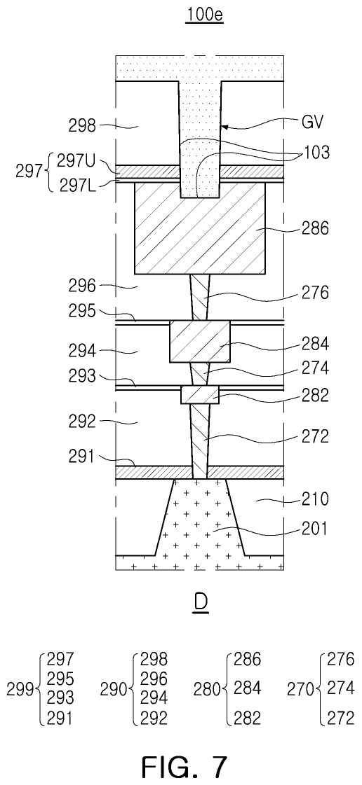

FIG. 7 is a partially enlarged view of a semiconductor device according to example embodiments. FIG. 7 illustrates an enlarged region corresponding to region ‘D’ in FIG. 1, according to an example embodiment.

Referring to FIG. 7, in the semiconductor device 100e, unlike the example embodiment of FIG. 2, top surfaces of the second and third lower protective layers 293 and 295 may be respectively located at substantially the same level as the upper surfaces of the first and second lower interconnection lines 282 and 284. The second and third lower protective layers 293 and 295 may have a structure in which they are cut off by the first and second lower interconnection lines 282 and 284.

The fourth lower protective layer 297 may have a double layer structure in which a second sub-protective layer 297U comprising silicon nitride is stacked on a first sub-protective layer 297L comprising aluminum oxide. The fourth lower protective layer 297 may have a thickness ranging from about 350 Å to about 2100 Å.

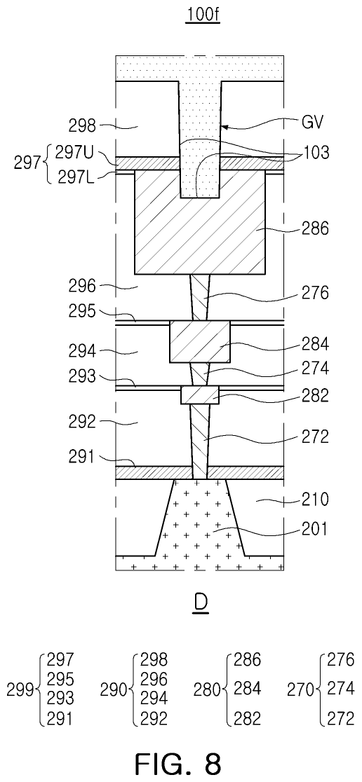

FIG. 8 is a partially enlarged view of a semiconductor device according to example embodiments. FIG. 8 illustrates an enlarged region corresponding to region ‘D’ of FIG. 1, according to an example embodiment.

Referring to FIG. 8, in the semiconductor device 100f, unlike in the example embodiment of FIG. 2, top surfaces of the second and third lower protective layers 293 and 295 may be located at substantially the same level as the upper surfaces of the first and second lower interconnection lines 282 and 284. The second and third lower protective layers 293 and 295 may have a structure in which they are cut off by the first and second lower interconnection lines 282 and 284.

The fourth lower protective layer 297 may have a double layer structure in which a second sub-protective layer 297U comprising silicon nitride is stacked on a first sub-protective layer 297L comprising aluminum oxide. The fourth lower protective layer 297 may have a thickness in a range of about 350 Å to about 2100 Å. An upper surface of the first sub-protective layer 297L may be positioned at substantially the same level as an upper surface of the third lower interconnection line 286. The first sub-protective layer 297L may have a structure that is broken by the third lower interconnection line 286.

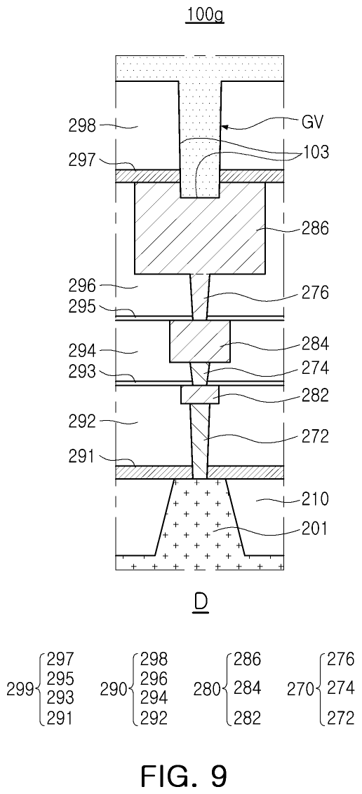

FIG. 9 is a partially enlarged view of a semiconductor device according to example embodiments. FIG. 9 illustrates an enlarged region corresponding to region ‘D’ in FIG. 1, according to an example embodiment.

Referring to FIG. 9, in the semiconductor device 100g, unlike the example embodiment of FIG. 2, the third lower contact plug 276 may have an integrated shape with no boundary between the third lower contact plug 276 and the third lower interconnection line 286. Such an integrated form may be formed by a dual damascene process.

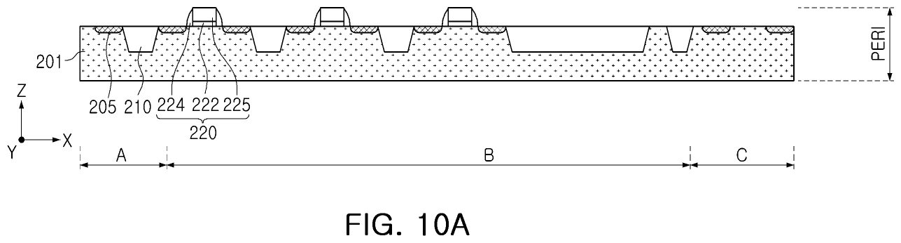

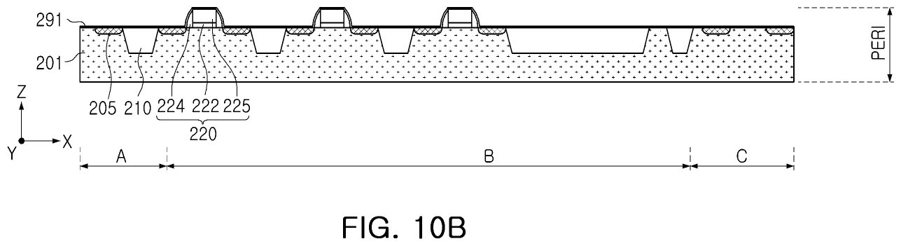

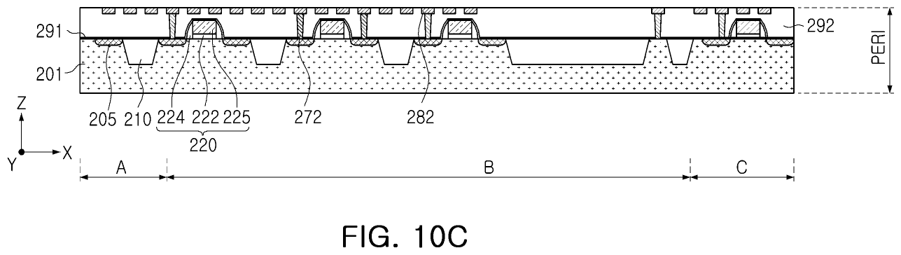

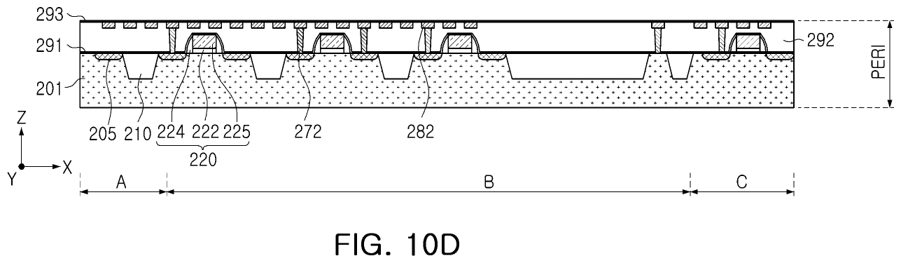

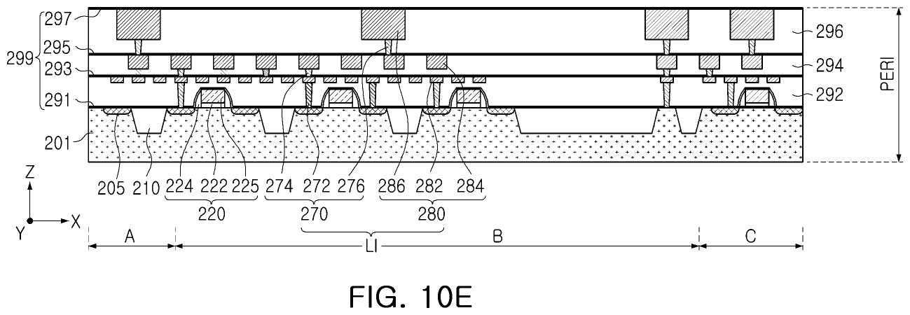

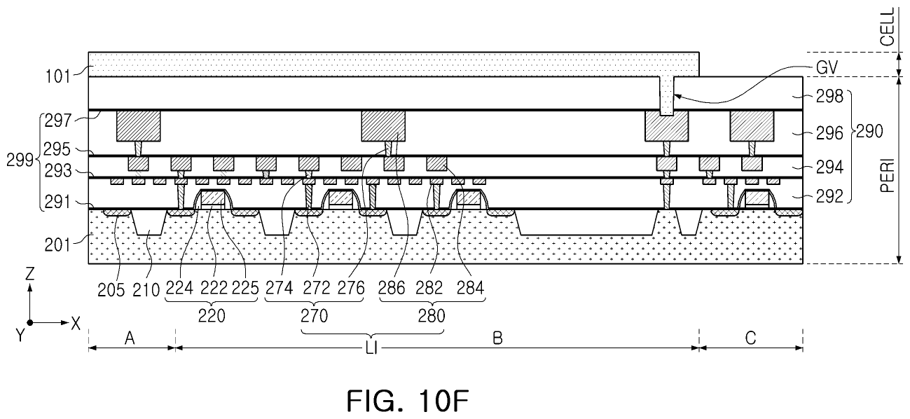

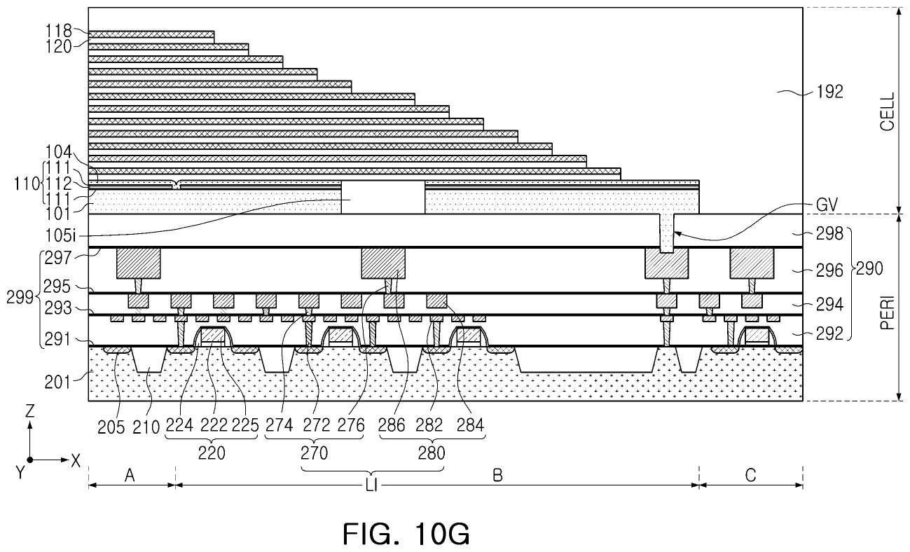

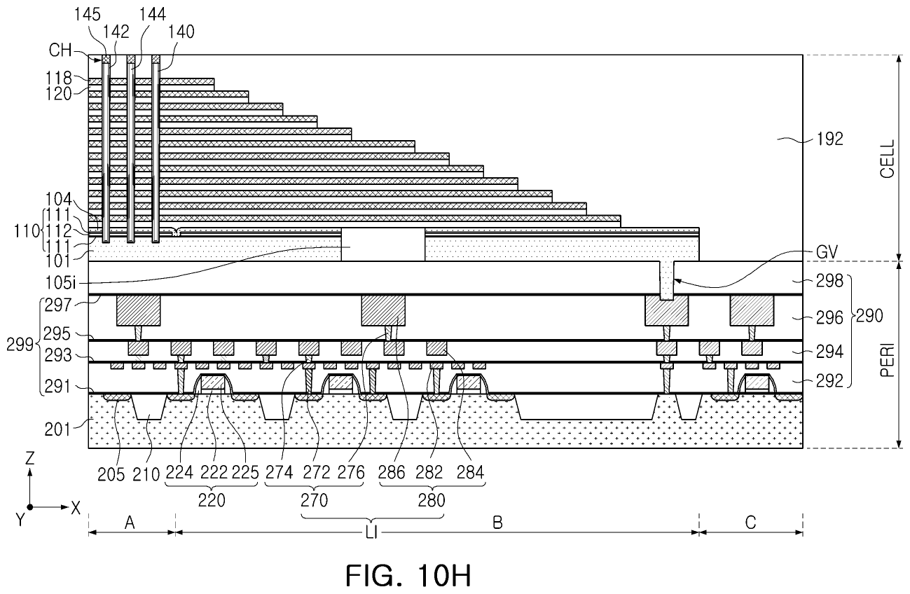

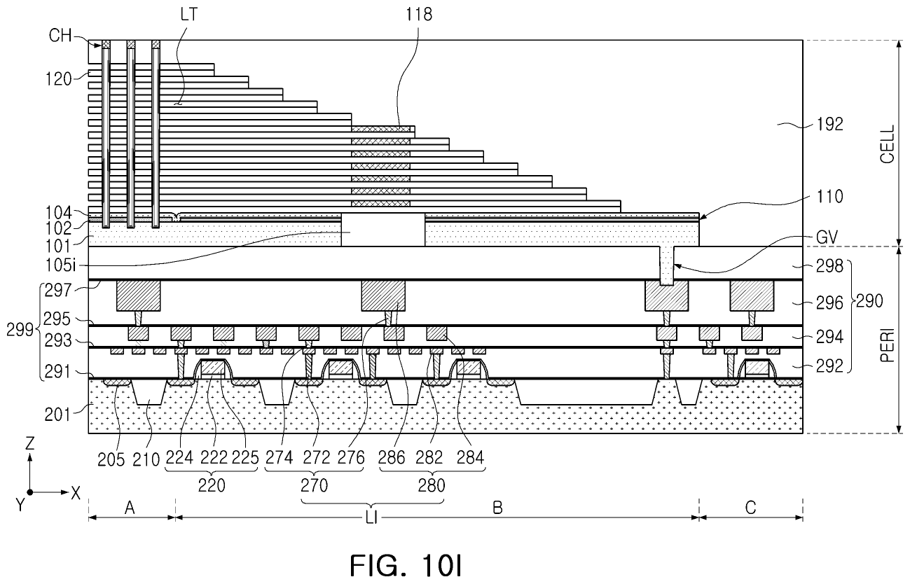

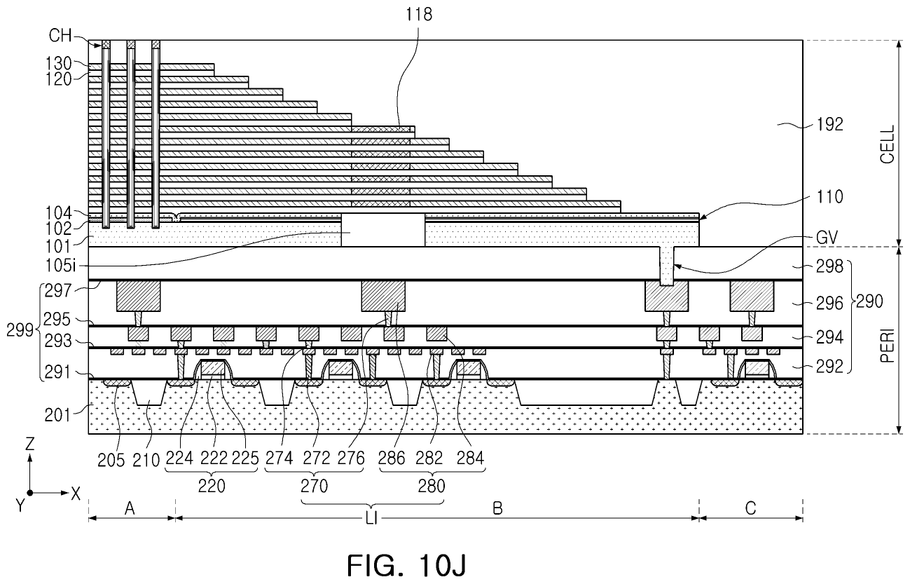

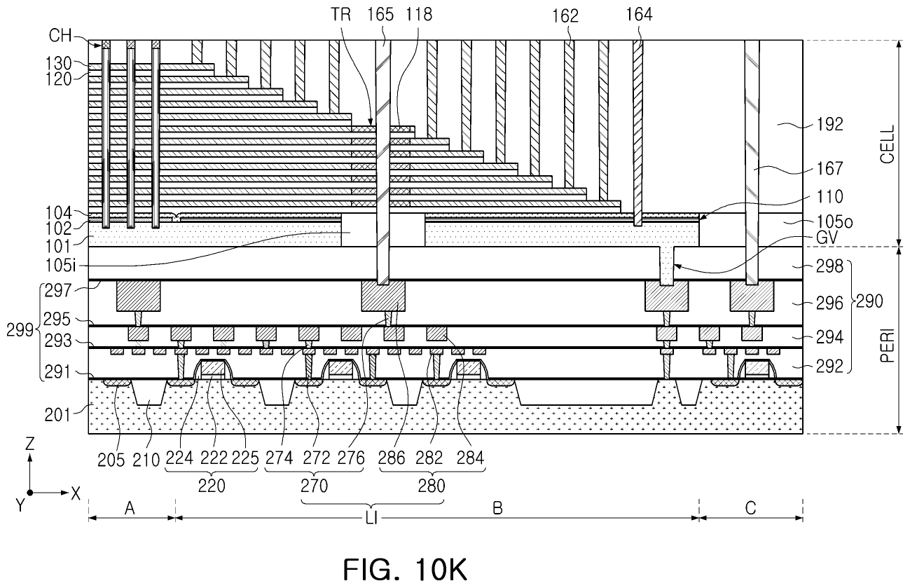

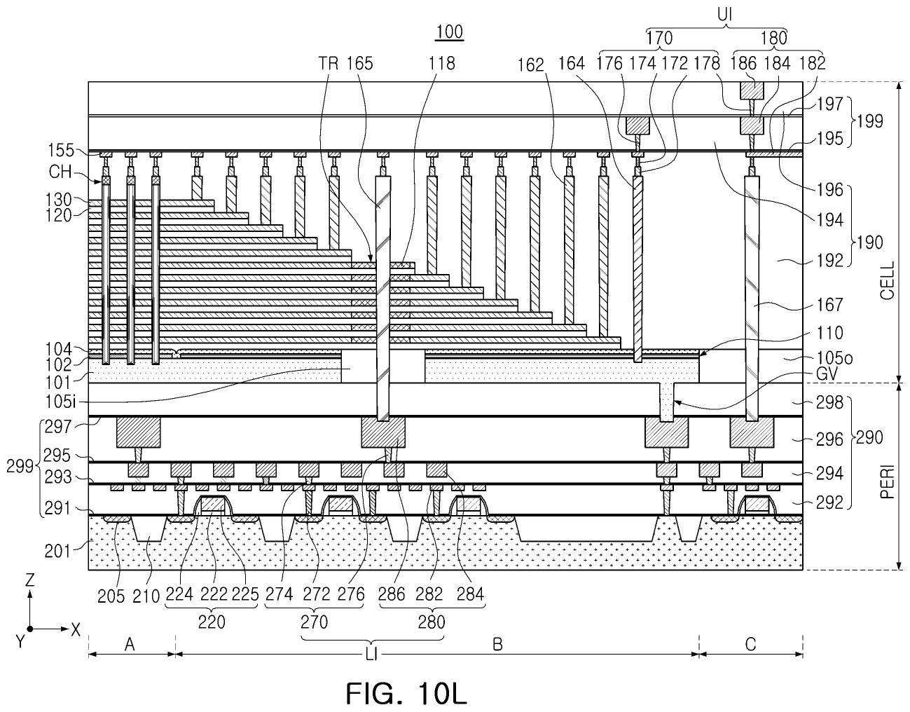

FIGS. 10A, 10B, 10C, 10D, 10E, 10F, 10G, 10H, 10I, 10J, 10K and 10L are schematic cross-sectional views for explaining a method of manufacturing a semiconductor device according to example embodiments. In FIGS. 10A, 10B, 10C, 10D, 10E, 10F, 10G, 10H, 10I, 10J, 10K and 10L, regions corresponding to the region illustrated in FIG. 1A are illustrated.

Referring to an example embodiment shown in FIG. 10A, circuit elements 220 may be formed on the first substrate 201.

First, device isolation layers 210 may be formed in a first substrate 201, and a circuit gate dielectric layer 222 and a circuit gate electrode 225 may be sequentially formed on the first substrate 201. The device isolation layers 210 may be formed by, for example, a shallow trench isolation (STI) process. The circuit gate dielectric layer 222 may be formed of silicon oxide, and the circuit gate electrode 225 may be formed of at least one of polycrystalline silicon, metal, metal nitride, or a metal-semiconductor compound, however, example embodiments are not limited thereto. Next, a spacer layer 224 and source/drain regions 205 may be formed on both sidewalls of the circuit gate dielectric layer 222 and the circuit gate electrode 225. In some example embodiments, the spacer layer 224 may be formed of a plurality of layers, and an ion implantation process may be performed to form the source/drain regions 205.

Referring to an example embodiment shown in FIG. 10B, on the first substrate 201 using atomic layer deposition (ALD) or chemical vapor deposition (CVD), by depositing silicon nitride or aluminum oxide, a first lower protective layer 291 may be formed.

Referring to an example embodiment shown in FIG. 10C, first lower contact plugs 272, first lower interconnection lines 282, and a first peripheral region insulating layer 292 may be formed.

A portion of the first lower contact plugs 272 may be removed by etching after forming the first peripheral region insulating layer 292, and may be formed by embedding a conductive material. The first lower interconnection lines 282 may be formed by, for example, depositing a conductive material and then patterning it.

Referring to an example embodiment shown in FIG. 10D, by depositing silicon nitride or aluminum oxide on the first lower interconnection lines 282 using atomic layer deposition (ALD) or chemical vapor deposition (CVD), a second lower protective layer 293 may be formed.

Referring to an example embodiment shown in FIG. 10E, second and third lower contact plugs 274 and 276, second and third lower interconnection lines 284 and 286, and second and third peripheral region insulating layers 294 and 296 may be formed.

The second and third lower contact plugs 274 and 276 may be formed by forming the second and third peripheral region insulating layers 294 and 296, respectively, and then by removing some of the same by etching and filling the conductive material. The second and third lower interconnection lines 284 and 286 may be formed by, for example, depositing a conductive material and then patterning it.

Referring to an example embodiment shown in FIG. 10F, a fourth peripheral region insulating layer 298, a second substrate 101, and an upper via GV may be formed.

By forming the fourth peripheral region insulating layer 298, all of the peripheral circuit regions PERI may be formed.

By removing the fourth peripheral region insulating layer 298 and the fourth lower protective layer 297, a via hole may be formed, and an upper via GV may be formed by filling the via hole. The second substrate 101 may be formed of, for example, polycrystalline silicon, and may be formed by a CVD process. Polycrystalline silicon forming the second substrate 101 may include impurities, for example, n-type impurities. After the second substrate 101 is formed on the entire fourth peripheral region insulating layer 298, the second substrate 101 may be patterned and removed from a partial region including the third region C of the memory cell region CELL.

Referring to an example embodiment shown in FIG. 10G, the first and second source sacrificial layers 111 and 112 and the second horizontal conductive layer 104 may be formed, and after forming the substrate insulating layers 105i and 105o, the sacrificial insulating layers 118 and the interlayer insulating layers 120 may be alternately stacked.

The first and second source sacrificial layers 111 and 112 may be stacked on the second substrate 101 such that the first source sacrificial layers 111 may be disposed above and below the second source sacrificial layer 112. The first and second source sacrificial layers 111 and 112 may include different materials. The first and second source sacrificial layers 111 and 112 may be layers replaced with the first horizontal conductive layer 102 of FIG. 1A through a subsequent process. For example, the first source sacrificial layer 111 may be formed of the same material as the interlayer insulating layers 120, the second source sacrificial layer 112 may be formed of the same material as the sacrificial insulating layers 118. The second horizontal conductive layer 104 may be formed on the first and second source sacrificial layers 111 and 112.

The inner substrate insulating layer 105i may be formed in the region where the through-interconnection region TR (see FIG. 1A) is located, and the first and second source sacrificial layers 111 and 112, the second horizontal conductive layer 104, and the second substrate 101 are partially removed, by filling an insulating material.

The sacrificial insulating layers 118 may be partially replaced by the gate electrodes 130 (refer to FIG. 1A) through a subsequent process. The sacrificial insulating layers 118 may be formed of a material different from that of the interlayer insulating layers 120, and the interlayer insulating layers 120 may be formed of a material that may be etched with etch selectivity under specific etch conditions. For example, the interlayer insulating layer 120 may be formed of at least one of silicon oxide and silicon nitride, and the sacrificial insulating layers 118 may be formed of a material different from that of the interlayer insulating layer 120 selected from silicon, silicon oxide, silicon carbide, and silicon nitride. In example embodiments, the thicknesses of the interlayer insulating layers 120 may not all be the same. According to various example embodiments, the thickness of the interlayer insulating layers 120 and the sacrificial insulating layers 118 and the number of films constituting the same may be variously changed from those illustrated.

A photolithography process and etching for the sacrificial insulating layers 118 may be performed using a mask layer so that the upper sacrificial insulating layers 118 extend shorter than the lower sacrificial insulating layers 118 in the second region B. The process may be repeated. Accordingly, the sacrificial insulating layers 118 may form a step-like structure in a predetermined configuration.

Next, a first cell region insulating layer 192 covering the stacked structure of the sacrificial insulating layers 118 and the interlayer insulating layers 120 may be formed.

Referring to an example embodiment shown in FIG. 10H, channel structures CH passing through the stacked structure of the sacrificial insulating layers 118 and the interlayer insulating layers 120 may be formed.

First, upper isolation regions SS (refer to FIG. 1B) may be formed by removing portions of the sacrificial insulating layers 118 and the interlayer insulating layers 120. The upper separation regions SS may be formed by exposing a region where the upper isolation regions SS are to be formed by using a separate mask layer, removing a predetermined number of sacrificial insulating layers 118 and interlayer insulating layers 120 from an uppermost portion, and then depositing an insulating material.

The channel structures CH may be formed by anisotropically etching the sacrificial insulating layers 118 and the interlayer insulating layers 120, and may be formed by forming hole-shaped channel holes and then filling the same. Due to the height of the stack structure, sidewalls of the channel structures CH may not be perpendicular to the top surface of the second substrate 101. The channel structures CH may be formed to recess a portion of the second substrate 101. Next, at least a portion of the gate dielectric layer 145, the channel layer 140, the channel insulating layer 144, and the channel pads 155, may be sequentially formed in the channel structures CH.

The gate dielectric layer 145 may be formed to have a uniform thickness using an ALD or CVD process. In this operation, all or part of the gate dielectric layer 145 may be formed, and a portion extending perpendicularly to the second substrate 101 along the channel structures CH may be formed. The channel layer 140 may be formed on the gate dielectric layer 145 in the channel structures CH. The channel insulating layer 144 may be formed to fill the channel structures CH, and may be an insulating material. However, in some example embodiments, the space between the channel layers 140 may be filled with a conductive material instead of the channel insulating layer 144. The channel pad 155 may be formed of a conductive material, for example, polycrystalline silicon.

Referring to an example embodiment shown in FIG. 10I, in regions corresponding to the first and second separation regions MS1 and MS2 (see FIG. 1B), openings may be formed to penetrate through the stacked structure of the sacrificial insulating layers 118 and the interlayer insulating layers 120, and tunnel portions LT may be formed by removing a portion of the sacrificial insulating layers 118 through the openings.

First, after forming separate sacrificial spacer layers in the openings, the second source sacrificial layer 112 may be selectively removed, and thereafter, the first source sacrificial layers 111 may be removed. The first and second source sacrificial layers 111 and 112 may be removed by, for example, a wet etching process. In the process of removing the first source sacrificial layers 111, a portion of the gate dielectric layer 145 exposed in the region where the second source sacrificial layer 112 is removed may also be removed. After forming the first horizontal conductive layer 102, by depositing a conductive material in the region where the first and second source sacrificial layers 111 and 112 are removed, the sacrificial spacer layers may be removed in the openings. The horizontal insulating layer 110 may be replaced with the first horizontal conductive layer 102 on the first region A, and may remain on the second region B.

Next, the sacrificial insulating layers 118 may be removed from the outside of the through interconnection region TR (refer to FIG. 1A). The sacrificial insulating layers 118 may remain in the through-interconnection region TR to form an insulating region of the through-interconnection region TR together with the interlayer insulating layers 120. The sacrificial insulating layers 118 may be selectively removed with respect to the interlayer insulating layers 120 using, for example, wet etching. Accordingly, a plurality of tunnel portions LT may be formed between the interlayer insulating layers 120.

A region in which the through-interconnection region TR is formed may be a region in which the sacrificial insulating layers 118 remain because the etchant does not reach the region spaced apart from the openings. Accordingly, the through-interconnection region TR may be formed in the center of the first and second separation regions MS1 and MS2 between the adjacent first and second separation regions MS1 and MS2.

Referring to an example embodiment shown in FIG. 10J, the gate electrodes 130 may be formed by filling the tunnel portions LT in which the sacrificial insulating layers 118 may be partially removed with a conductive material.

The conductive material forming the gate electrodes 130 may fill the tunnel portions LT. Side surfaces of the gate electrodes 130 may contact side surfaces of the sacrificial insulating layers 118 of the through-interconnection region TR. The conductive material may include a metal, polycrystalline silicon, or a metal silicide material. After the gate electrodes 130 are formed, the conductive material deposited in the openings may be removed through an additional process, and then the isolation insulating layer 108 (refer to FIG. 1B) may be formed by filling the insulating material.

Referring to an example embodiment shown in FIG. 10K, gate contacts 162 passing through the first cell region insulating layer 192, a substrate contact 164, and first and second through vias 165 and 167 may be formed.

The gate contacts 162 may be formed to be connected to the gate electrodes 130 in the second region B, and the substrate contact 164 may be formed to be connected to the second substrate 101 at an end of the second region B. The first through via 165 may be formed to be connected to the first interconnection structure LI of the peripheral circuit region PERI in the through-interconnection region TR, and the second through via 167 may be formed to be connected to the first interconnection structure LI of the peripheral circuit region PERI in the third region C.

The gate contacts 162, the substrate contact 164, and the first and second through vias 165 and 167 may be formed to have different depths, and by simultaneously forming contact holes by using an etch stop layer, or the like, the contact holes may be filled with a conductive material. However, in some example embodiments, some of the gate contacts 162, the substrate contact 164, and the first and second through vias 165 and 167 may be formed in different process operations.

Referring to an example embodiment shown in FIG. 10L, second and third cell region insulating layers 194 and 196, first and second upper protective layers 195 and 197, and an upper interconnection structure UI may be formed.

The upper contact plugs 170 of the upper interconnection structure UI may be formed by forming a portion of the cell region insulating layer 290, removing a portion by etching, and filling a conductive material. The upper interconnection lines 180 may be formed by, for example, depositing a conductive material and then patterning it.

Accordingly, the semiconductor device 100 of FIGS. 1A, 1B and 2 may be finally manufactured.

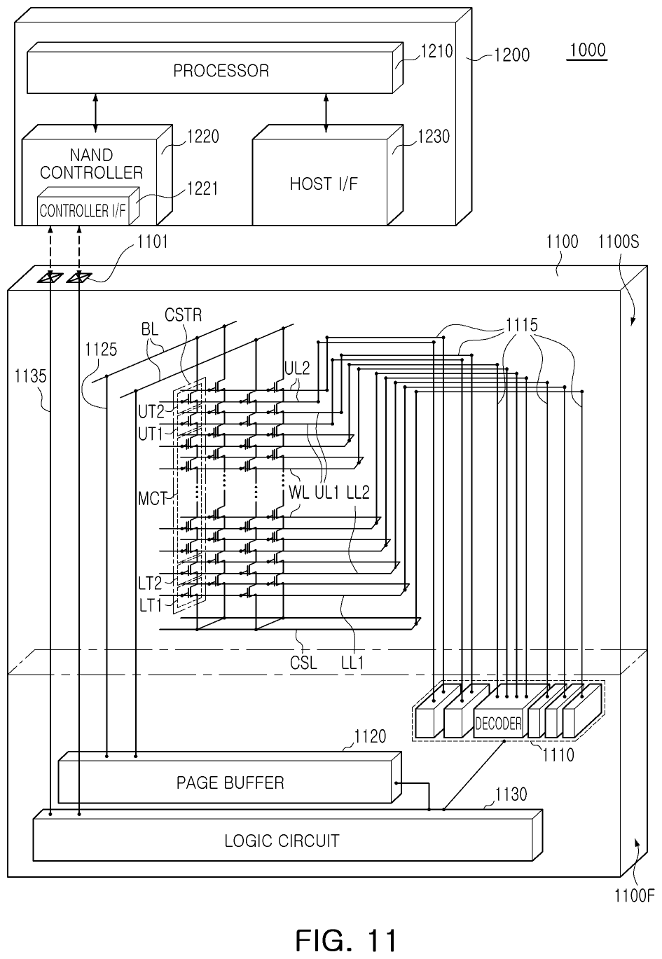

FIG. 11 is a diagram schematically illustrating an electronic system including a semiconductor device according to example embodiments.

Referring to FIG. 11, an electronic system 1000 may include a semiconductor device 1100 and a controller 1200 electrically connected to the semiconductor device 1100. The electronic system 1000 may be a storage device including one or a plurality of semiconductor devices 1100 or an electronic device including a storage device. For example, the electronic system 1000 may be a solid state drive device (SSD), a universal serial bus (USB), a computing system, a medical device, or a communication device, including one or a plurality of semiconductor devices 1100. In an example embodiment, the electronic system 1000 may be an electronic system storing data.

The semiconductor device 1100 may be a nonvolatile memory device, for example, the NAND flash memory device described above with reference to FIGS. 1A, 1B, 2, 3, 4, 5, 6, 7, 8 and 9. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including bitlines BL, a common source line CSL, word lines WL, first and second upper gate lines UL1 and UL2, first and second lower gate lines LL1 and LL2, and memory cell strings (CSTR) between the bitlines BL and the common source line CSL.

In the second structure 1100S, each of the memory cell strings CSTR may include lower transistors LT1 and LT2 adjacent to the common source line (CSL), upper transistors UT1 and UT2 adjacent to the bitlines BL, and a plurality of memory cell transistors (MCT) disposed between the lower transistors LT1 and LT2 and the upper transistors UT1 and UT2. The number of the lower transistors LT1 and LT2 and the number of the upper transistors UT1 and UT2 may be variously modified according to example embodiments.

In example embodiments, the upper transistors UT1 and UT2 may include a string select transistor, and the lower transistors LT1 and LT2 may include a ground select transistor. The lower gate lines LL1 and LL2 may be gate electrodes of the lower transistors LT1 and LT2, respectively. The word lines (WL) may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT using the GIDL phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the inside of the first structure 1100F to the second structure 1100S. The bitlines BL may be electrically connected to the page buffer 1120 through second connection interconnections 1125 extending from the inside of the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may further include an input/output pad 1101. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the inside of the first structure 1100F to the second structure 1100S.

The controller 1200 may include a processor 1210, a NAND controller 1220, and a host interface 1230. In some example embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to a predetermined firmware, and may access the semiconductor device 1100 by controlling the NAND controller 1220. The NAND controller 1220 may include a controller interface 1221 that processes communication with the semiconductor device 1100. Through the controller interface 1221, a control command for controlling the semiconductor device 1100, data to be written to the memory cell transistors MCT of the semiconductor device 1100, data to be read from the memory cell transistors MCT, and the like may be transmitted. The host interface 1230 may provide a communication function between the electronic system 1000 and an external host. When receiving a control command from an external host through the host interface 1230, the processor 1210 may control the semiconductor device 1100 in response to the control command.

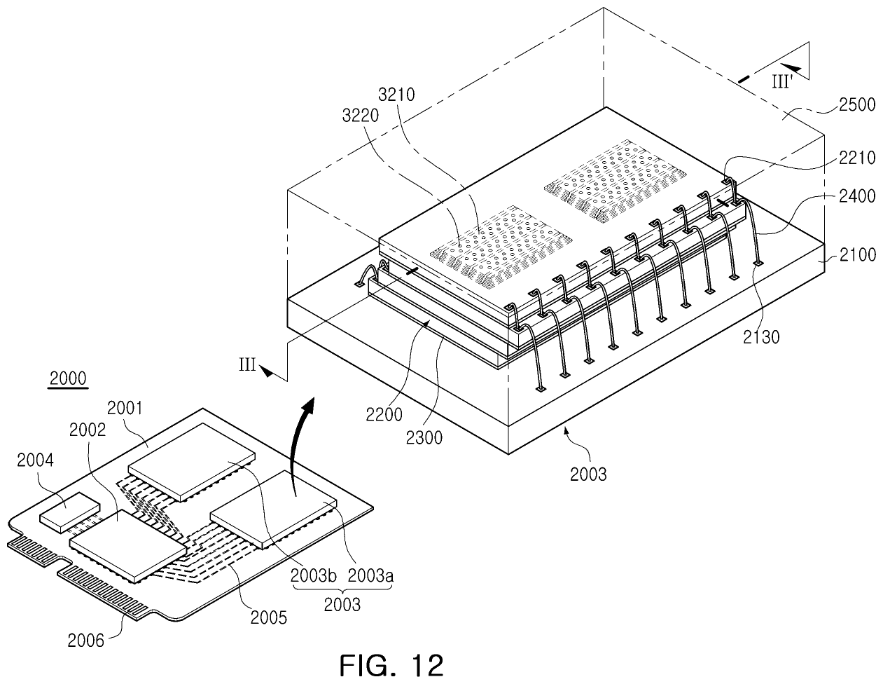

FIG. 12 is a schematic perspective view of an electronic system including a semiconductor device according to an example embodiment.

Referring to FIG. 12, an electronic system 2000 according to an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary according to a communication interface between the electronic system 2000 and the external host. In example embodiments, the electronic system 2000 may communicate with an external host according to any one of the interfaces such as a Universal Serial Bus (USB), Peripheral Component Interconnect Express (PCI-Express), Serial Advanced Technology Attachment (SATA), an M-Phy for Universal Flash Storage (UFS), and the like. In example embodiments, the electronic system 2000 may operate by power supplied from an external host through the connector 2006. The electronic system 2000 may further include a power management integrated circuit (PMIC) for distributing power supplied from the external host to the controller 2002 and the semiconductor package 2003.

The controller 2002 may write data to or read data from the semiconductor package 2003, and may improve the operating speed of the electronic system 2000.

The DRAM 2004 may be a buffer memory for reducing a speed difference between the semiconductor package 2003 as a data storage space and an external host. The DRAM 2004 included in the electronic system 2000 may also operate as a kind of cache memory, and may provide a space for temporarily storing data in a control operation for the semiconductor package 2003. For example, when the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on lower surfaces of the semiconductor chips 2200, respectively, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 11. Each of the semiconductor chips 2200 may include gate stack structure 3210 and memory channel structure 3220. Each of the semiconductor chips 2200 may include the semiconductor device described above with reference to FIGS. 1A, 1B, 2, 3, 4, 5, 6, 7, 8 and 9.

In example embodiments, the connection structure 2400 may be a bonding wire electrically connecting the input/output pad 2210 and the upper package pads 2130. Accordingly, in each of the first and second semiconductor packages 2003a and 2003b, the semiconductor chips 2200 may be electrically connected to each other by a bonding wire method, and may be electrically connected to the upper package pads 2130 of the package substrate 2100. According to example embodiments, in each of the first and second semiconductor packages 2003a and 2003b, the semiconductor chips 2200 may also be electrically connected to each other by a connection structure including a Through Silicon Via (TSV) instead of the connection structure 2400 of the bonding wire method.

In example embodiments, the controller 2002 and the semiconductor chips 2200 may be included in one package. In an example embodiment, the controller 2002 and the semiconductor chips 2200 may be mounted on a separate interposer substrate different from the main board 2001, and the controller 2002 and the semiconductor chips 2200 may be connected to each other by interconnections formed on the interposer substrate.

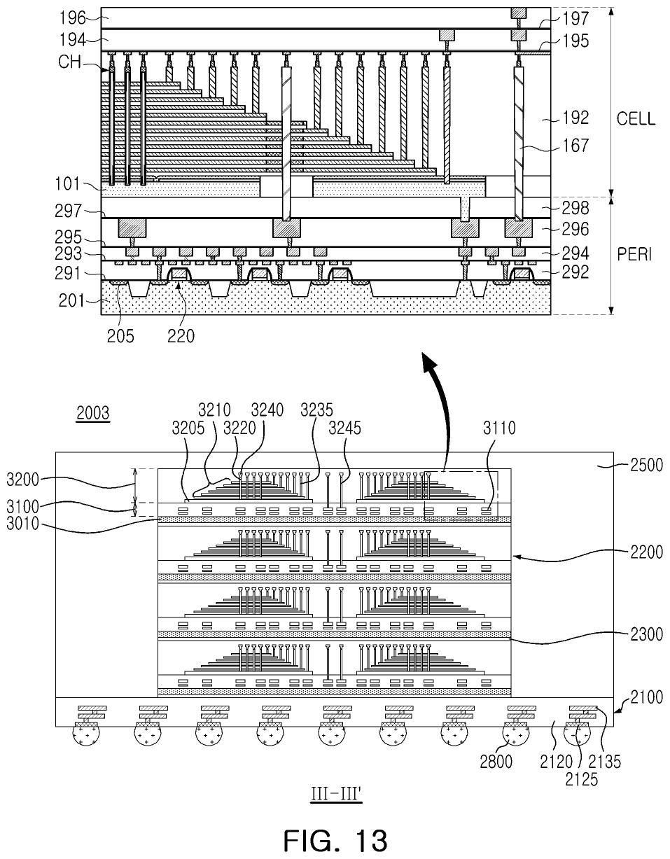

FIG. 13 is a cross-sectional view schematically illustrating a semiconductor package according to an example embodiment. FIG. 13 illustrates an example embodiment of the semiconductor package 2003 of FIG. 12, and conceptually illustrates a region taken along line of the semiconductor package 2003 of FIG. 12.

Referring to FIG. 13, in the semiconductor package 2003, the package substrate 2100 may be a printed circuit board. The package substrate 2100 may include a package substrate body 2120, upper package pads 2130 (see FIG. 12) disposed on an upper surface of the package substrate body 2120, lower package pads 2125 disposed on or exposed through the lower surface of the package substrate body 2120, and internal interconnections 2135 electrically connecting the upper package pads 2130 and the lower package pads 2125 inside the package substrate body 2120. The upper package pads 2130 may be electrically connected to the connection structures 2400. The lower package pads 2125 may be connected to the interconnection patterns 2005 of the main board 2001 of the electronic system 2000 as illustrated in FIG. 12 through conductive connection portions 2800.

Each of the semiconductor chips 2200 may include a semiconductor substrate 3010, and a first structure 3100 and a second structure 3200 that are sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, memory channel structure 3220 and separation regions 3230 passing through the gate stack structure 3210, bitlines 3240 electrically connected to the memory channel structure 3220, and gate contact plugs 3235 electrically connected to the word lines WL of the gate stack structure 3210 (see FIG. 11). As described above with reference to FIGS. 1A, 1B, 2, 3, 4, 5, 6, 7, 8 and 9, each of the semiconductor chips 2200 may further include lower protective layers 299 having lower hydrogen permeability than silicon nitride, below the peripheral region insulating layers 290.

Each of the semiconductor chips 2200 may include a through interconnection 3245 electrically connected to the peripheral interconnections 3110 of the first structure 3100 and extending into the second structure 3200. The through interconnection 3245 may be disposed outside the gate stack structure 3210, and may be further disposed to pass through the gate stack structure 3210. Each of the semiconductor chips 2200 may further include an input/output pad 2210 (refer to FIG. 12) electrically connected to the peripheral interconnections 3110 of the first structure 3100.

As set forth above, by including the lower protective layer disposed below the peripheral region insulating layer, a semiconductor device having improved electrical characteristics and reliability and an electronic system including the same may be provided.

While example embodiments have been illustrated and described above, it will be apparent to those skilled in the art that modifications and variations could be made without departing from the spirit and scope as defined by the appended claims.

What is claimed is:

1. A semiconductor device comprising:
a peripheral circuit region comprising:
a first substrate;
circuit elements disposed on the first substrate;
a first interconnection structure electrically connected to the circuit elements;
a first peripheral region insulating layer covering the circuit elements;
a second peripheral region insulating layer disposed on the first peripheral region insulating layer;
a third peripheral region insulating layer disposed on the second peripheral region insulating layer; and
a fourth peripheral region insulating layer disposed on the third peripheral region insulating layer; and
a memory cell region comprising:
a second substrate disposed on the peripheral circuit region and having a first region and a second region;
gate electrodes stacked on the first region of the second substrate and spaced apart from each other in a first direction perpendicular to an upper surface of the second substrate, and extending in a stepped shape in a second direction perpendicular to the first direction, on the second region of the second substrate;
interlayer insulating layers alternately stacked with the gate electrodes;
a cell region insulating layer covering the gate electrodes;
channel structures passing through the gate electrodes and vertically extending from the second substrate, each of the channel structures comprising a channel layer; and
a second interconnection structure electrically connected to the gate electrodes and the channel structures,
wherein the peripheral circuit region further comprises:
a first lower protective layer disposed below the first peripheral region insulating layer;
a second lower protective layer disposed between the first peripheral region insulating layer and the second peripheral region insulating layer;
a third lower protective layer disposed between the second peripheral region insulating layer and the third peripheral region insulating layer; and
a fourth lower protective layer disposed between the third peripheral region insulating layer and the fourth peripheral region insulating layer,
wherein at least one of the first lower protective layer, the second lower protective layer, the third lower protective layer, and the fourth lower protective layer comprises a hydrogen diffusion barrier layer configured to inhibit a hydrogen element in the cell region insulating layer from diffusing to the circuit elements, and
wherein the hydrogen diffusion barrier layer comprises aluminum oxide.

2. The semiconductor device of claim 1, wherein the first lower protective layer comprises silicon nitride, and
wherein each of the second lower protective layer and the third lower protective layer comprises the hydrogen diffusion barrier layer.

3. The semiconductor device of claim 2, wherein the fourth lower protective layer comprises silicon nitride.

4. The semiconductor device of claim 2, wherein the fourth lower protective layer comprises the hydrogen diffusion barrier layer.

5. The semiconductor device of claim 2, wherein the fourth lower protective layer comprises:
a first sub-protective layer; and
a second sub-protective layer disposed on the first sub-protective layer,
wherein the first sub-protective layer comprises the hydrogen diffusion barrier layer, and
wherein the second sub-protective layer comprises silicon nitride.

6. The semiconductor device of claim 2, wherein the first interconnection structure comprises a first lower interconnection line, a second lower interconnection line, and a third lower interconnection line disposed on different levels,
wherein the second lower protective layer covers an upper surface of the first lower interconnection line,
wherein the third lower protective layer covers an upper surface of the second lower interconnection line, and
wherein the fourth lower protective layer covers an upper surface of the third lower interconnection line.

7. The semiconductor device of claim 2, wherein the first interconnection structure comprises a first lower interconnection line, a second lower interconnection line, and a third lower interconnection line disposed on different levels,
wherein an upper surface of the second lower protective layer is coplanar with an upper surface of the first lower interconnection line,
wherein an upper surface of the third lower protective layer is coplanar with an upper surface of the second lower interconnection line, and
wherein the fourth lower protective layer covers an upper surface of the third lower interconnection line.

8. The semiconductor device of claim 3, wherein each of the first lower protective layer and the fourth lower protective layer has a thickness in a range of about 300 Å to 2000 Å, and
wherein each of the second lower protective layer and the third lower protective layer has a thickness in a range of about 50 Å to about 100 Å.

9. The semiconductor device of claim 4, wherein the first lower protective layer has a thickness in a range of about 300 Å to about 2000 Å, and
wherein each of the second lower protective layer, the third lower protective layer, and the fourth lower protective layer has a thickness in a range of about 50 Å to about 100 Å.

10. The semiconductor device of claim 5, wherein each of the first lower protective layer and the fourth lower protective layer has a thickness in a range of about 300 Å to about 2000 Å,
wherein the second lower protective layer has a thickness in a range of about 50 Å to about 100 Å, and
wherein the third lower protective layer has a thickness in a range of about 350 Å to about 2100 Å.

11. The semiconductor device of claim 3, wherein the memory cell region further comprises a through via passing through the gate electrodes and the fourth peripheral region insulating layer to electrically connect the first interconnection structure and the second interconnection structure, and
wherein the through via passes through the fourth lower protective layer.

12. The semiconductor device of claim 3, wherein the memory cell region further comprises an upper via connecting the first substrate and the second substrate,
wherein the upper via extends from the second substrate, and
wherein the upper via passes through the fourth lower protective layer.

13. The semiconductor device of claim 2, wherein the first interconnection structure comprises:
a first lower interconnection line, a second lower interconnection line, and a third lower interconnection line; and
a first lower contact plug, a second lower contact plug, and a third lower contact plug,
wherein the first lower interconnection line interfaces with the first lower contact plug,
wherein the second lower interconnection line interfaces with the second lower contact plug, and
wherein the third lower interconnection line is integrally connected to the third lower contact plug.

14. A semiconductor device comprising:
a first substrate;
circuit elements disposed on the first substrate;
a first lower protective layer covering the circuit elements;
a first peripheral region insulating layer disposed on the first lower protective layer;
a first lower interconnection structure penetrating through the first peripheral region insulating layer, the first lower interconnection structure comprising a first lower contact plug and a first lower interconnection line;
a second lower protective layer disposed on the first peripheral region insulating layer;
a second peripheral region insulating layer disposed on the second lower protective layer;
a second lower interconnection structure penetrating through the second peripheral region insulating layer, the second lower interconnection structure comprising a second lower contact plug and a second lower interconnection line;
a third lower protective layer disposed on the second peripheral region insulating layer;
a third peripheral region insulating layer disposed on the third lower protective layer;
a third lower interconnection structure penetrating through the third peripheral region insulating layer, the third lower interconnection structure comprising a third lower contact plug and a third lower interconnection line;
a fourth lower protective layer disposed on the third peripheral region insulating layer;
a fourth peripheral region insulating layer disposed on the fourth lower protective layer;
a memory structure disposed on the fourth peripheral region insulating layer, the memory structure comprising gate electrodes and channel structures passing through the gate electrodes;
a first cell region insulating layer disposed on the fourth peripheral region insulating layer and covering the memory structure; and
a first upper protective layer, a second cell region insulating layer, a second upper protective layer, and a third cell region insulating layer sequentially stacked on the first cell region insulating layer,
wherein a thickness of the third lower interconnection line is greater than a thickness of each of the first lower interconnection line and the second lower interconnection line,
wherein a thickness of each of the second lower protective layer and the third lower protective layer is less than a thickness of each of the first lower protective layer and the fourth lower protective layer and a thickness of each of the first upper protective layer and the second upper protective layer,
wherein each of the second lower protective layer and the third lower protective layer comprises a second material different from a first material of the first lower protective layer and the fourth lower protective layer,
wherein each of the second lower protective layer and the third lower protective layer comprises a hydrogen diffusion barrier layer configured to inhibit a hydrogen element each of in the first cell region insulating layer, the second cell region insulating layer, and the third cell region insulating layer from diffusing to the circuit elements, and the hydrogen diffusion barrier layer comprises the second material, and
wherein the second material is aluminum oxide.

15. The semiconductor device of claim 14, wherein each of the first lower protective layer and the fourth lower protective layer comprises silicon nitride.

16. The semiconductor device of claim 14, wherein each of the first lower protective layer and the fourth lower protective layer has a thickness in a range of about 300 Å to 2000 Å, and
wherein each of the second lower protective layer and the third lower protective layer has a thickness in a range of about 50 Å to about 100 Å.

17. The semiconductor device of claim 14, wherein the semiconductor device further comprises a through via passing through the gate electrodes and the fourth peripheral region insulating layer, and
wherein the through via passes through the fourth lower protective layer.

18. The semiconductor device of claim 17, wherein the semiconductor device further comprises an upper via penetrating through the fourth peripheral region insulating layer, and
wherein the upper via passes through the fourth lower protective layer.

19. An electronic system comprising:
a semiconductor device comprising:
a first substrate;
circuit elements on the first substrate;
a first lower protective layer covering the circuit elements;
a first peripheral region insulating layer disposed on the first lower protective layer;
a first lower interconnection structure penetrating through the first peripheral region insulating layer, the first lower interconnection structure comprising a first lower contact plug and a first lower interconnection line;
a second lower protective layer disposed on the first peripheral region insulating layer;
a second peripheral region insulating layer disposed on the second lower protective layer;
a second lower interconnection structure penetrating through the second peripheral region insulating layer, the second lower interconnection structure comprising a second lower contact plug and a second lower interconnection line;
a third lower protective layer disposed on the second peripheral region insulating layer;
a third peripheral region insulating layer disposed on the third lower protective layer;
a third lower interconnection structure penetrating through the third peripheral region insulating layer, the third lower interconnection structure comprising a third lower contact plug and a third lower interconnection line;
a fourth lower protective layer disposed on the third peripheral region insulating layer;
a fourth peripheral region insulating layer disposed on the fourth lower protective layer;
a memory structure disposed on the fourth peripheral region insulating layer, the memory structure comprising gate electrodes and channel structures passing through the gate electrodes;
a first cell region insulating layer disposed on the fourth peripheral region insulating layer and covering the memory structure; and
a first upper protective layer, a second cell region insulating layer, a second upper protective layer and a third cell region insulating layer sequentially stacked on the first cell region insulating layer, and input/output pads electrically connected to the circuit elements,
wherein a thickness of the third lower interconnection line is greater than a thickness of each of the first lower interconnection line and the second lower interconnection line,
wherein a thickness of each of the second lower protective layer and the third lower protective layer is less than a thickness of each of the first lower protective layer, the fourth lower protective layer, and a thickness of each of the first upper protective layer, the second upper protective layer,
wherein each of the second lower protective layer and the third lower protective layer comprises a second material different from a first material of the first upper protective layer and the fourth lower protective layer,
wherein each of the second upper protective layer and the third lower protective layer comprises a hydrogen diffusion barrier layer comprising the second material and configured to inhibit a hydrogen element in each of the first cell region insulating layer, the second cell region insulating layer, and the third cell region insulating layer from diffusing to the circuit elements; and
a controller electrically connected to the semiconductor device through the input/output pads and configured to control the semiconductor device.

20. The electronic system of claim 19, wherein each of the first lower protective layer and fourth lower protective layer comprises silicon nitride.
